(19) United States
(12) Patent Application Publication
(10) Pub. No.: US 2026/0372062 A1
(43) Pub. Date: Nov. 19, 2026

(54) SEMICONDUCTOR STRUCTURE AND METHOD FOR FORMING THE SAME

(71) Applicant: United Microelectronics Corp., Hsinchu (TW)

(72) Inventor: Chia-Chen SUN, Kaohsiung City (TW)

(21) Appl. No.: 19/243,774

(22) Filed: Jun. 20, 2025

(30) Foreign Application Priority Data
May 14, 2025 (TW) 114118097

(51) Int. Cl. H10W 20/41; H10W 20/00

(52) U.S. Cl. CPC H10W 20/435; H10W 20/056; H10W 20/089

(57) ABSTRACT

A semiconductor structure and a method for forming the same are provided. The semiconductor structure includes a conductive line and a via structure on the conductive line. The via structure includes a first via portion, a second via portion and a connection portion connected between the first via portion and the second via portion. A depth of the connection portion is smaller than a depth of the first via portion and a depth of the second via portion.

This application claims the benefit of Taiwan application Serial No. 114118097, filed May 14, 2025, the subject matters of which are incorporated herein by reference.

### BACKGROUND

### Technical Field

The disclosure relates to a semiconductor structure and a method for forming the same.

### Description of the Related Art

The photolithography process is an important step in the semiconductor manufacturing process. The photolithography process can be used to transfer the layout patterns of integrated circuits (ICs) from the photomask to the photoresist layer on the surface of the semiconductor wafer or the substrate, and then transfer the layout patterns of the integrated circuits to the semiconductor wafer or substrate.

As the complexity and integration of integrated circuits increases, the size of components continues to shrink. After the photolithography process, the integrity of the layout patterns on the surface of the semiconductor wafer or the substrate will deteriorate. In other words, the difference between the circuit patterns on the surface of the semiconductor wafer or the substrate and the original layout pattern becomes larger. For example, when a via structure is formed on a conductive line with a small area, it is often observed that the via structure on the conductive line with a small area does not show a proper electrical connection, resulting in a short circuit.

### SUMMARY

The present disclosure provides a semiconductor structure and a method for forming the same, which includes a connection portion connected between the first via portion and the second via portion to ensure that the via structure on the conductive line with a small area has a proper electrical connection.

According to an embodiment of the present disclosure, a semiconductor structure is provided. The semiconductor structure includes a conductive line and a via structure on the conductive line. The via structure includes a first via portion, a second via portion and a connection portion connected between the first via portion and the second via portion. A depth of the connection portion is smaller than a depth of the first via portion and a depth of the second via portion.

According to an embodiment of the present disclosure, a method for forming a semiconductor structure is provided. The method includes: providing a first layout pattern comprising a plurality of first patterns; providing a second layout pattern comprising a plurality of second patterns; overlapping the first layout pattern and the second layout pattern to determine whether at least two first patterns overlap a second pattern of the plurality of second patterns; inspecting the second layout pattern to determine whether a length of the second pattern is equal to or substantially equal to 3.8 times to 4.8 times a length of a first pattern of the at least two first patterns; modifying the first layout pattern to add at least one connection pattern between the at least two first patterns.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a method for forming a semiconductor structure according to some embodiments of the present disclosure.

FIG. 2 shows overlapping layout patterns according to some embodiments of the present disclosure.

FIG. 3 shows overlapping layout patterns according to some embodiments of the present disclosure.

FIG. 4 illustrates a schematic cross-sectional view of a semiconductor structure according to some embodiments of the present disclosure.

FIG. 5 shows overlapping layout patterns according to some embodiments of the present disclosure.

FIG. 6 shows overlapping layout patterns according to some embodiments of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. In the following method forming a semiconductor structure, there may be one or more additional operations between the operations described, and the order of the operations may vary. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Additionally, the term “electrically connected” used in the specification and claims can refer to current passing through elements, or an operational relation between elements. The operational relation may mean, for example, that one element is used to drive another element, but current may not flow directly between these two elements.

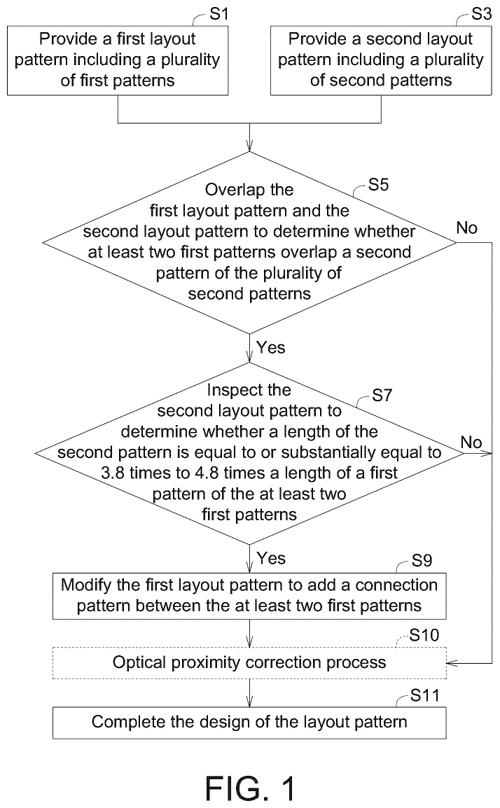

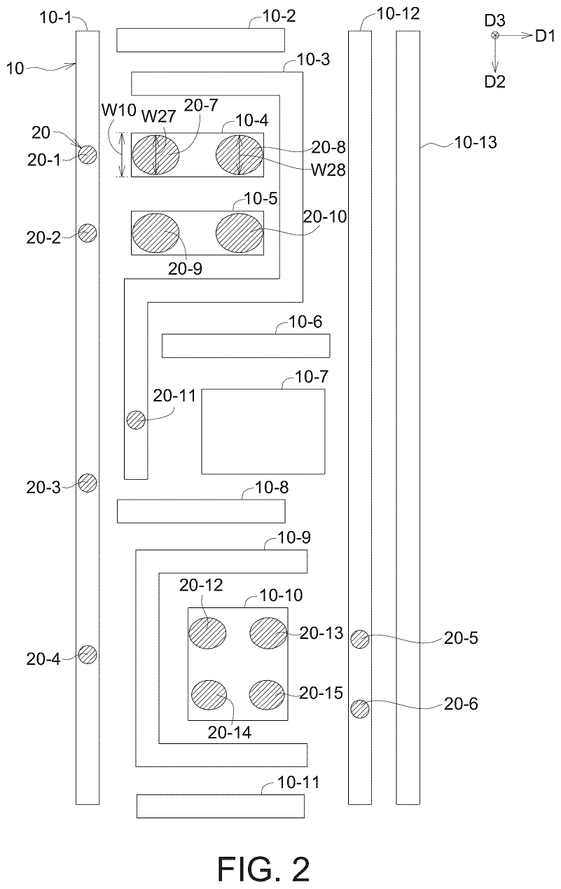

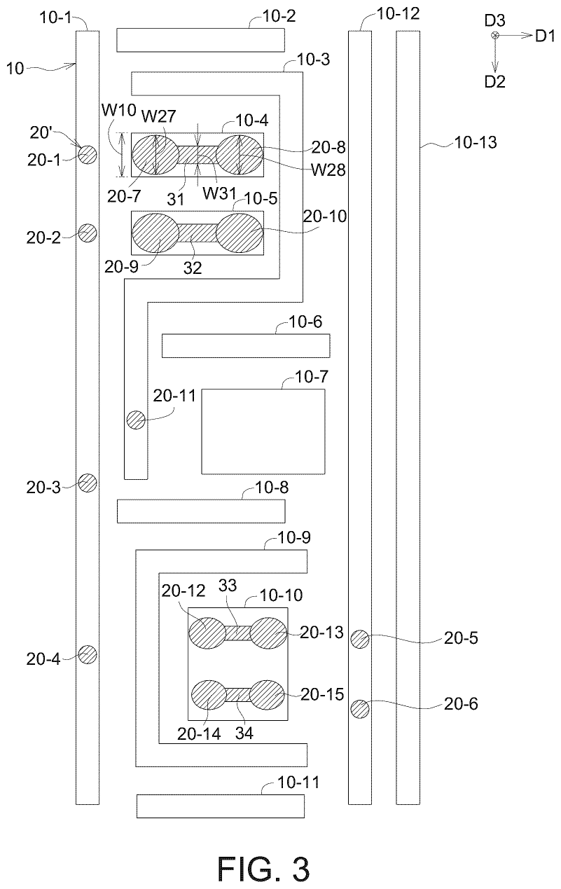

Referring to FIGS. 1 to 3, FIG. 1 shows a method for forming a semiconductor structure according to some embodiments of the present disclosure, FIG. 2 shows the overlapping first layout pattern and second layout pattern according to some embodiments of the present disclosure, and FIG. 3 shows the overlapping modified first layout pattern and second layout pattern according to some embodiments of the present disclosure. As shown in FIG. 1, the method for forming a semiconductor structure can include a step S1, a step S3, a step S5, a step S7, a step S9 and a step S11.

Step S1: provide a first layout pattern 20 including a plurality of first patterns 20-1~20-15 (as shown in FIG. 2). The first patterns 20-1~20-15 may be separated from each other. The first patterns 20-1~20-15 may have different sizes and shapes.

Step S3: provide a second layout pattern 10 including a plurality of second patterns 10-1~10-13 (as shown in FIG. 2). The second patterns 10-1~10-13 may be separated from each other. The second patterns 10-1~10-13 may have different sizes and shapes.

Step S5: overlap the first layout pattern 20 and the second layout pattern 10 to determine whether at least two first patterns overlap a second pattern of the plurality of second patterns 10-1~10-13. Take FIG. 2 as an example, when the first layout pattern 20 overlaps the second layout pattern 10, the first patterns 20-1 to 20-4 overlap the second pattern 10-1, the first pattern 20-11 overlaps the second pattern 10-3, the first patterns 20-5 and 20-6 overlap the second pattern 10-12, the first patterns 20-7 and 20-8 overlap the second pattern 10-4, the first patterns 20-9 and 20-10 overlap the second pattern 10-5, and the first patterns 20-12 to 20-15 overlap the second pattern 10-10. In response to step S5 finding at least two first patterns overlapping a second pattern, for example, the first patterns 20-1 to 20-4 overlapping the second pattern 10-1, the first patterns 20-5 and 20-6 overlapping the second pattern 10-12, the first patterns 20-7 and 20-8 overlapping the second pattern 10-4, the first patterns 20-9 and 20-10 overlapping the second pattern 10-5, and the first patterns 20-12 to 20-15 overlapping the second pattern 10-10 in FIG. 2, step S7 can then be performed. In response to step S5 not finding at least two first patterns overlapping a second pattern, step S7 and step S9 can be omitted and step S10 and/or step S11 can then be performed.

Step S7: inspect the second layout pattern 10 to determine whether a length of the second pattern is equal to or substantially equal to 3.8 times to 4.8 times a length of a first pattern of the at least two first patterns overlapping the second pattern. Take FIG. 2 as an example, step S7 can inspect the second layout pattern 10 to determine whether a length of the second pattern 10-1 is equal to or substantially equal to 3.8 times to 4.8 times a length of one of the first patterns 20-1 to 20-4; step S7 can inspect the second layout pattern 10 to determine whether a length of the second pattern 10-12 is equal to or substantially equal to 3.8 times to 4.8 times a length of one of the first patterns 20-5 and 20-6; step S7 can inspect the second layout pattern 10 to determine whether a length of the second pattern 10-4 is equal to or substantially equal to 3.8 times to 4.8 times a length of one of the first patterns 20-7 and 20-8; step S7 can inspect the second layout pattern 10 to determine whether a length of the second pattern 10-5 is equal to or substantially equal to 3.8 times to 4.8 times a length of one of the first patterns 20-9 and 20-10; step S7 can inspect the second layout pattern 10 to determine whether a length of the second pattern 10-10 is equal to or substantially equal to 3.8 times to 4.8 times a length of one of the first patterns 20-12 to 20-15. The lengths of the second pattern and the first pattern overlapping the second pattern are in the same direction. The length of each second pattern of the second layout pattern is defined along the current direction of the second pattern, and therefore the lengths of the second patterns can be in different directions. For example, the lengths of the second patterns 10-1, 10-12 and 10-13 are in the second direction D2, the lengths of the second patterns 10-2, 10-6, 10-8 and 10-11 are in the first direction D1, the lengths of portions of the second pattern 10-3 extending along the first direction D1 are in the first direction D1, the lengths of portions of the second pattern 10-3 extending along the second direction D2 are in the second direction D2, and the lengths of the second patterns 10-4, 10-5 and 10-10 are in the first direction D1. The first direction D1 is perpendicular to the second direction D2. In response to step S7 finding that the length of the second pattern, such as the second patterns 10-4, 10-5 and 10-10, is equal to or substantially equal to 3.8 times to 4.8 times the length of the first pattern of the at least two first patterns overlapping the second pattern, step S9 can then be performed. In response to step S7 not finding that the length of the second pattern is equal to or substantially equal to 3.8 to 4.8 times the length of the first pattern of the at least two first patterns overlapping the second pattern, step S9 can be omitted and step S10 and/or step S11 can then be performed.

Step S9: modify the first layout pattern to add at least one connection pattern between the at least two first patterns. At least one connection pattern can be connected between the at least two first patterns. For example, the first layout pattern 20 shown in FIG. 2 can be modified to add a connection pattern 31 between the first patterns 20-7 and 20-8, add a connection pattern 32 between the first patterns 20-9 and 20-10, add a connection pattern 33 between the first patterns 20-12 and 20-13, and add a connection pattern 34 between the first patterns 20-14 and 20-15, and therefore a modified first layout pattern 20′ as shown in FIG. 3 can be obtained. The connection pattern 31 is connected between the first patterns 20-7 and 20-8. The connection pattern 32 is connected between the first patterns 20-9 and 20-10. The connection pattern 33 is connected between the first patterns 20-12 and 20-13. The connection pattern 34 is connected between the first patterns 20-14 and 20-15. A width of the connection pattern may be smaller than or equal to a width of the first pattern connected to the connection pattern. For example, the width W31 of the connection pattern 31 in the second direction D2 may be smaller than the width W27 of the first pattern 20-7 in the second direction D2 and may be smaller than the width W28 of the first pattern 20-8 in the second direction D2. The connection pattern and two first patterns connected to the connection pattern may be arranged along the direction of length. For example, the connection pattern 31, the first pattern 20-7 and the first pattern 20-8 may be arranged along the first direction D1; the connection pattern 32, the first pattern 20-9 and the first pattern 20-10 may be arranged along the first direction D1; the connection pattern 33, the first pattern 20-12 and the first pattern 20-13 may be arranged along the first direction D1; the connection pattern 34, the first pattern 20-14 and the first pattern 20-15 may be arranged along the first direction D1. The present embodiment shows that the connection patterns extend along the first direction D1, but the present disclosure is not limited thereto. In other embodiments, the connection pattern can extend along the second direction D2 and be connected between two first patterns.

Step S11: complete the design of the layout pattern.

In an embodiment, the method for forming a semiconductor structure may include other steps performed before, after or between step S1, step S3, step S5, step S7, step S9 and step S11. In an embodiment, optionally, the method for forming a semiconductor structure can include determining whether a width of the second pattern is equal to or substantially equal to a width of the at least two first patterns overlapping the second pattern; this step is performed before or after step S7; this step is performed before step S9. Take FIG. 2 as an example, this step can inspect the first layout pattern 20 and the second layout pattern 10 to determine whether the width of the second pattern 10-4 (such as the width W10) is equal to or substantially equal to the width of one of the first patterns 20-7 and 20-8 (such as one of the widths W27 and W28), this step can inspect the first layout pattern 20 and the second layout pattern 10 to determine whether the width of the second pattern 10-5 is equal to or substantially equal to the width of one of the first patterns 20-9 and 20-10, this step can inspect the first layout pattern 20 and the second layout pattern 10 to determine whether the width of the second pattern 10-10 is equal to or substantially equal to the width of one of the first patterns 20-12 to 20-15, this step can inspect the first layout pattern 20 and the second layout pattern 10 to determine whether the width of the second pattern 10-1 is equal to or substantially equal to the width of one of the first patterns 20-1 to 20-4, and this step can inspect the first layout pattern 20 and the second layout pattern 10 to determine whether the width of the second pattern 10-12 is equal to or substantially equal to the width of one of the first patterns 20-5 and 20-6. The widths of the second pattern and the first pattern overlapping the second pattern are in the same direction. The width of the second pattern is defined along a direction perpendicular to the current direction of the second pattern, and therefore the widths of the second patterns can be in different directions. For example, the widths of the second patterns 10-1, 10-12 and 10-13 are in the first direction D1, the widths of the second patterns 10-2, 10-6, 10-8 and 10-11 are in the second direction D2, the widths of portions of the second pattern 10-3 extending along the first direction D1 are in the second direction D2, the widths of portions of the second pattern 10-3 extending along the second direction D2 are in the first direction D1, and the widths of the second patterns 10-4, 10-5 and 10-10 are in the second direction D2. In response to this step finding whether the width of the second pattern is equal to or substantially equal to the width of at least two first patterns overlapping this second pattern, step S9 may then be performed.

In an embodiment, the conditions for determining to modify the first layout pattern to add a connection pattern can be set to only “the length of the second pattern is equal to or substantially equal to 3.8 to 4.8 times the length of a first pattern of at least two first patterns overlapping the second pattern” (step S7); under this condition, the step of determining the width of the second pattern can be omitted. In the present embodiment, when the length of the second pattern is equal to or substantially equal to 3.8 to 4.8 times the length of a first pattern of at least two first patterns overlapping the second pattern, this second pattern can be understood as a pattern with a small area, and a conductive line formed through this second pattern can be understood as a conductive line with a small area.

In an embodiment, the conditions for determining to modify the first layout pattern to add a connection pattern can be set to both “the length of the second pattern is equal to or substantially equal to 3.8 to 4.8 times the length of a first pattern of at least two first patterns overlapping the second pattern” (step S7) and “the width of the second pattern is equal to or substantially equal to a width of the at least two first patterns overlapping the second pattern”; under this condition, in response to step not finding that the width of the second pattern is equal to or substantially equal to a width of the at least two first patterns overlapping the second pattern, step S9 can be omitted and step S10 and/or step S11 can then be performed. In the present embodiment, when the length of the second pattern is equal to or substantially equal to 3.8 to 4.8 times the length of a first pattern of at least two first patterns overlapping the second pattern, and the width of the second pattern is equal to or substantially equal to a width of the at least two first patterns overlapping the second pattern, this second pattern can be understood as a pattern with a small area, and a conductive line formed through this second pattern can be understood as a conductive line with a small area. In other embodiment, the conditions for determining to modify the first layout pattern to add a connection pattern can be set as “the length of the second pattern is equal to or substantially equal to 3.8 to 4.8 times the length of a first pattern of at least two first patterns overlapping the second pattern” (step S7) without satisfying “the width of the second pattern is equal to or substantially equal to a width of the at least two first patterns overlapping the second pattern”; that is, when the length of the second pattern is equal to or substantially equal to 3.8 to 4.8 times the length of a first pattern of at least two first patterns overlapping the second pattern, this second pattern can be understood as a pattern with a small area, and a conductive line formed through this second pattern can be understood as a conductive line with a small area.

In an embodiment, optionally, the method for forming a semiconductor structure can include a step S10: perform an optical proximity correction (OPC) process after modifying the first layout pattern. Step S10 can be performed between step S9 and step S11. The optical proximity correction process may include: estimating or simulating the deformation caused when transferring the pattern of the photomask to the wafer, and correcting the pattern of the photomask (such as the line width of the pattern of the photomask), as such, an image that meets the original design can be obtained after the exposure with the photomask. The optical proximity correction process can reduce the problem of distortion during using the modified first layout pattern and the second layout pattern to form a semiconductor structure.

In an embodiment, step S7 and step S9 can be performed through a Boolean operation.

After step S11, a corresponding semiconductor structure can be formed according to the modified first layout pattern and the second layout pattern.

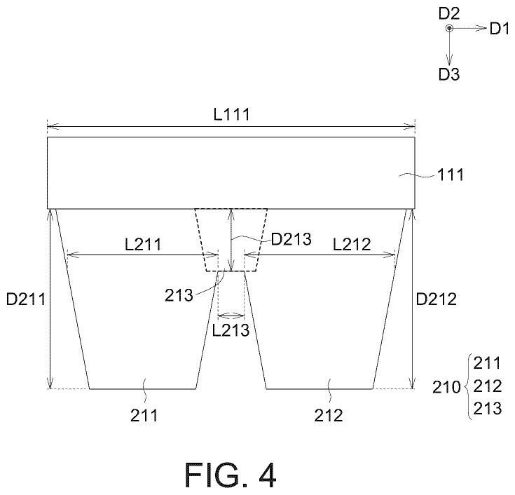

Hereinafter, illustrations will be provided using FIGS. 3 and 4 as examples, but the present invention is not limited thereto. After step S11, the method for forming a semiconductor structure can include: transferring the modified first layout pattern 20′ to a first photomask; providing a substrate and a first photoresist layer on the substrate; transferring the modified first layout pattern 20′ to the first photoresist layer; performing an etching process and a deposition process through the first photoresist layer to form a plurality of via portions and at least one connection portion in the substrate, wherein the via portions can correspond to the first patterns 20-1 to 20-15, and the at least one connection portion can correspond to the connection patterns 31 to 34. After step S11, the method for forming a semiconductor structure can include: transferring the second layout pattern 10 to a second photomask; providing a dielectric layer on the substrate and a second photoresist layer on the dielectric layer; transferring the second layout pattern to the second photoresist layer; performing an etching process and a deposition process through the second photoresist layer to form a plurality of conductive lines in the dielectric layer, wherein the conductive lines can correspond to the second patterns 10-1 to 10-13. After performing the steps described above, a schematic cross-sectional view of the formed conductive line and via structure on the conductive line is shown in FIG. 4. The via structure includes two via portions and a connection portion connected between two via portions. Two via portions and the connection portion connected between two via portions are electrically connected to each other. A surface of the connection portion facing away from the conductive line is substantially planar. The via portion can be electrically connected to the conductive line overlapping this via portion (in the third direction D3). As shown in FIG. 4, via structure 210 may include a via portion 211, a via portion 212 and a connection portion 213 connected between the via portion 211 and the via portion 212; the via portion 211, the via portion 212, the connection portion 213 connected between the via portion 211 and the via portion 212 and the conductive line 111 are electrically connected to each other; a surface of the connection portion 213 facing away from the conductive line 111 (i.e. the surface connected to the via portion 211 and the via portion 212) is substantially planar. The conductive line 111 may be a metal layer, such as the metal layer M1, M2, M3 . . . . The via portion 211, the via portion 212, the connection portion 213 and conductive line 111 shown in FIG. 4 can correspond to the first pattern 20-7, the first pattern 20-8, the connection pattern 31 and the second pattern 10-4 shown in FIG. 3 respectively, or can correspond to the first pattern 20-9, the first pattern 20-10, the connection pattern 32 and the second pattern 10-5 shown in FIG. 3 respectively, or can correspond to the first pattern 20-12, the first pattern 20-13, the connection pattern 33 and the second pattern 10-10 shown in FIG. 3 respectively, or can correspond to the first pattern 20-14, the first pattern 20-15, the connection pattern 34 and the second pattern 10-10 shown in FIG. 3 respectively. The first direction D1, the second direction D2 and the third direction D3 are perpendicular to each other.

The substrate may include a semiconductor material and/or a dielectric material. For example, the semiconductor material may be silicon, germanium, silicon germanium, silicon carbide, gallium arsenide, gallium phosphide, indium phosphide, indium arsenide, Indium antimonide, or any combination thereof. For example, the dielectric material may be silicon oxide, silicon nitride, or any combination thereof. The substrate may include active devices and/or passive devices. In an embodiment, the substrate is a semiconductor wafer. In an embodiment, the substrate is a dielectric substrate. The first photoresist layer and the second photoresist layer may include any photoresist material known in the art. The preceding etching process may be a dry etching process or a wet etching process. The preceding deposition process may be a chemical vapor deposition (CVD) process, a plasma-enhanced chemical vapor deposition (PECVD) process, a physical vapor deposition (PVD) process, an atomic layer deposition (ALD) process, a plasma-enhanced atomic layer deposition (PEALD) process, or an epitaxial growth process.

The conductive line and the via structure may include conductive materials, such as aluminum, copper, copper alloys, tungsten, tungsten alloys, cobalt, cobalt alloys, or any combination thereof. The conductive line and the via structure may be formed in dielectric layers. The dielectric layer may include a dielectric material, such as silicon oxide, borophosphosilicate glass (BPSG), tetraethoxysilane (TEOS), spin-on glass (SOG), undoped silicate glass (USG), fluorinated silicate glass (FSG), high-density plasma (HDP) oxide, plasma-enhanced TEOS (PETEOS), or any combination thereof.

As shown in FIG. 4, a depth D213 of the connection portion 213 in the third direction D3 can be small than a depth D211 of the via portion 211 in the third direction D3 and a depth D212 of the via portion 212 in the third direction D3. The depth D211 of the via portion 211 and the depth D212 of the via portion 212 are substantially the same. The via portion 211, the connection portion 213 and the via portion 212 are arranged along the first direction D1. The first pattern, the connection pattern and the second pattern can correspond to the via portion, the connection portion and the conductive line respectively, and therefore the size relationship between the first pattern, the connection pattern and the second pattern can also be applied to the size relationship between the via portion, the connection portion and the conductive line. The length L111 of the conductive line 111 in the first direction D1 is equal to or substantially equal to 3.8 times to 4.8 times the length L211 of the via portion 211 in the first direction D1, or 3.8 times to 4.8 times the length L212 of the via portion 212 in the first direction D1. In an embodiment, the length L111 of the conductive line 111 is equal to 3.8 times to 4.8 times the length L211 of the via portion 211±5 nm, or 3.8 times to 4.8 times the length L212 of the via portion 212 ±5 nm. The length L211 of the via portion 211 can be equal to or substantially equal to the length L212 of the via portion 212. The length L213 of the connection portion 213 in the first direction D1 can be equal to or substantially equal to 1.8 times to 2.8 times the length L211 of the via portion 211, or 1.8 times to 2.8 times the length L212 of the via portion 212.

A width (not shown in the drawings) of the conductive line 111 in the second direction D2 may be equal to or substantially equal to a width (not shown in the drawings) of the via portion 211 in the second direction D2, or a width (not shown in the drawings) of the via portion 212 in the second direction D2. The width of the via portion 211 in the second direction D2 may be equal to or substantially equal to the width of the via portion 212 in the second direction D2. The width of the conductive line 111 in the second direction D2 may be equal to or substantially equal to the width of the via portion 211 in the second direction D2, or the width of the via portion 212 in the second direction D2.

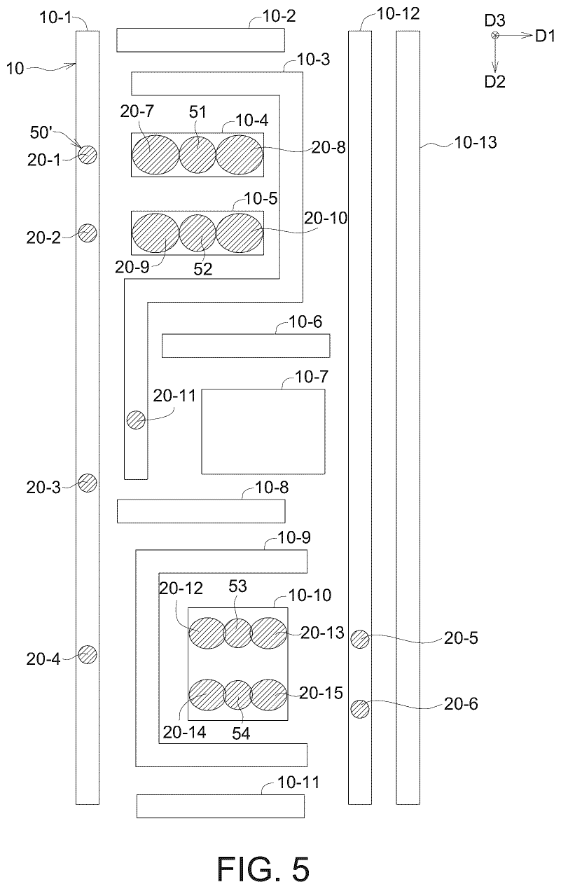

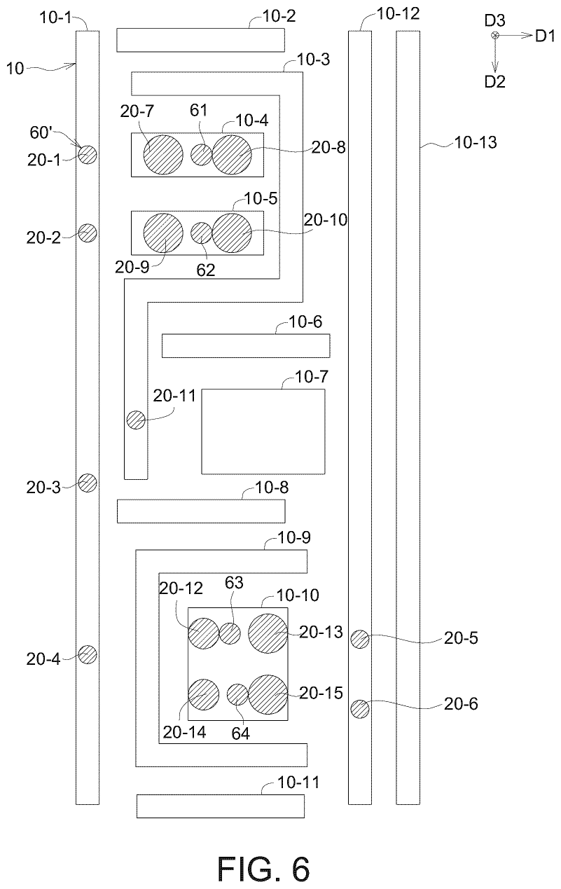

FIG. 3 illustrates one embodiment of a modified first layout pattern that can be applied to the present disclosure, though the present disclosure is not limited thereto. For example, the modified first layout pattern can have the configuration as shown in FIG. 5 or 6.

The difference between the modified first layout pattern 50′ of FIG. 5 and the modified first layout pattern 20′ is that the shapes of the connection patterns 51 to 54, the sizes of the connection patterns 51 to 54, and the positions of the connection patterns 51 to 54 relative to the first patterns are different from the shapes of the connection patterns 31 to 34, the sizes of the connection patterns 31 to 34, and the positions of the connection patterns 31 to 34 relative to the first patterns. The connection patterns 31 to 34 may have rectangular or strip shapes. The connection patterns 51 to 54 may have circular or elliptical shapes. The widths of the connection patterns 51 to 54 in the second direction D2 may be greater than the widths of the connection patterns 31 to 34 in the second direction D2. The widths of the connection patterns 51 to 54 in the second direction D2 may be smaller than or equal to the widths of the first patterns on opposite sides of the connection patterns in the second direction D2.

The difference between the modified first layout pattern 60′ of FIG. 6 and the modified first layout pattern 20′ is that the shapes of the connection patterns 61 to 64, the sizes of the connection patterns 61 to 64, and the positions of the connection patterns 61 to 64 relative to the first patterns are different from the shapes of the connection patterns 31 to 34, the sizes of the connection patterns 31 to 34, and the positions of the connection patterns 31 to 34 relative to the first patterns. The connection patterns 61 to 64 may have circular or elliptical shapes. The connection patterns 61 to 64 may be connected to only one of the two first patterns, for example, the connection pattern 61 may be connected to only the first pattern 20-8, the connection pattern 62 may be connected to only the first pattern 20-10, the connection pattern 63 may be connected to only the first pattern 20-12, and the connection pattern 64 may be connected to only the first pattern 20-15. The widths of the connection patterns 61 to 64 in the second direction D2 may be smaller than or equal to the widths of the first patterns on opposite sides of the connection patterns in the second direction D2.

When at least two via portions are formed on a conductive line with a small area, the depth of one of the via portions may be smaller than an expected depth, resulting in this via portion not being electrically connected to the conductive line (or metal layer) therebelow and causing a short circuit. The present disclosure provides a connection portion between at least two via portions on the conductive line with a small area, the connection portion is connected between the at least two via portions, which can prevent the depth of the via portion from being smaller than the expected depth, ensure a proper electrical connection between the via portion and the conductive line (or metal layer), and effectively reduce short circuit issues in semiconductor structures.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a conductive line; and
a via structure on the conductive line and comprising a first via portion, a second via portion and a connection portion connected between the first via portion and the second via portion,
wherein a depth of the connection portion is smaller than a depth of the first via portion and a depth of the second via portion.

2. The semiconductor structure according to claim 1, wherein the first via portion, the connection portion and the second via portion are arranged along a first direction, a length of the conductive line in the first direction is equal to or substantially equal to 3.8 times to 4.8 times a length of the first via portion in the first direction, or 3.8 times to 4.8 times a length of the second via portion in the first direction.

3. The semiconductor structure according to claim 2, wherein the length of the conductive line in the first direction is equal to 3.8 times to 4.8 times the length of the first via portion in the first direction ±5 nm, or 3.8 times to 4.8 times the length of the second via portion in the first direction ±5 nm.

4. The semiconductor structure according to claim 2, wherein a width of the conductive line in a second direction is equal to or substantially equal to a width of the first via portion in the second direction, or a width of the second via portion in the second direction, and the first direction is perpendicular to the second direction.

5. The semiconductor structure according to claim 4, wherein the length of the first via portion is equal to or substantially equal to the length of the second via portion.

6. The semiconductor structure according to claim 5, wherein the width of the first via portion is equal to or substantially equal to the width of the second via portion.

7. The semiconductor structure according to claim 1, wherein the first via portion, the connection portion and the second via portion are arranged along a first direction, a width of the conductive line in a second direction is equal to or substantially equal to a width of the first via portion in the second direction, or a width of the second via portion in the second direction, and the first direction is perpendicular to the second direction.

8. The semiconductor structure according to claim 1, wherein a length of the connection portion is equal to or substantially equal to 1.8 times to 2.8 times a length of the first via portion, or 1.8 times to 2.8 times a length of the second via portion.

9. The semiconductor structure according to claim 1, wherein a surface of the connection portion facing away from the conductive line is substantially planar.

10. The semiconductor structure according to claim 1, wherein the depth of the first via portion and the depth of the second via portion are substantially the same.

11. A method for forming a semiconductor structure, comprising:
providing a first layout pattern comprising a plurality of first patterns;
providing a second layout pattern comprising a plurality of second patterns;
overlapping the first layout pattern and the second layout pattern to determine whether at least two first patterns overlap a second pattern of the plurality of second patterns;
inspecting the second layout pattern to determine whether a length of the second pattern is equal to or substantially equal to 3.8 times to 4.8 times a length of a first pattern of the at least two first patterns; and
modifying the first layout pattern to add at least one connection pattern between the at least two first patterns.

12. The method according to claim 11, further comprising:
determining whether a width of the second pattern is equal to or substantially equal to a width of the at least two first patterns.

13. The method according to claim 11, further comprising:
performing an optical proximity correction (OPC) process after modifying the first layout pattern.

14. The method according to claim 13, further comprising:
providing a substrate and a first photoresist layer on the substrate;
transferring the modified first layout pattern to the first photoresist layer; and
performing an etching process and a deposition process through the first photoresist layer to form a plurality of via portions and at least one connection portion in the substrate, wherein the plurality of via portions correspond to the plurality of first patterns, and the at least one connection portion corresponds to the at least one connection pattern.

15. The method according to claim 14, further comprising:
providing a dielectric layer on the substrate and a second photoresist layer on the dielectric layer;
transferring the second layout pattern to the second photoresist layer;
performing another etching process and another deposition process through the second photoresist layer to form a plurality of conductive lines in the dielectric layer, wherein the plurality of conductive lines correspond to the plurality of second patterns.

16. The method according to claim 14, wherein a depth of the at least one connection portion is small than a depth of the plurality of via portions.

17. The method according to claim 11, wherein the at least one connection pattern is connected between the at least two first patterns.

18. The method according to claim 11, wherein the at least one connection pattern and the at least two first patterns are arranged along a first direction, and the length of the second pattern is in the first direction.

19. The method according to claim 11, further comprising:
providing a substrate and a first photoresist layer on the substrate;
transferring the modified first layout pattern to the first photoresist layer; and
performing an etching process and a deposition process through the first photoresist layer to form a plurality of via portions and at least one connection portion in the substrate, wherein the plurality of via portions correspond to the plurality of first patterns, the at least one connection portion corresponds to the at least one connection pattern, and the at least one connection portion is connected between two via portions of the plurality of via portions.
